(19) United States
(12) Patent Application Publication
(10) Pub. No.: US 2006/0071344 A1
(43) Pub. Date: Apr. 6, 2006

(54) Wiring connection structure and method for forming the same

(75) Inventor: Mizuhisa Nihei, Kawasaki (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 11/079,108

(22) Filed: Mar. 15, 2005

(30) Foreign Application Priority Data
Oct. 1, 2004 (JP) 2004-289720

(51) Int. Cl. H01L 23/48

(52) U.S. Cl. 257/774

(57) ABSTRACT

Disclosed is a wiring connection structure comprising a wiring on which a preferable carbon nanotube can be formed, and a method for forming the same. On a lower layer Cu wiring, Mo is deposited to form a connection layer. On this connection layer, a carbon nanotube is grown using a CVD method. When the connection layer composed of Mo is formed, the following advantages can be obtained. Even when heat is applied during the CVD for growing the carbon nanotube, thermal diffusion of Cu in the lower layer Cu wiring is suppressed so that activity of the catalyst metal can be kept. Further, since the contact resistance between Mo and the carbon nanotube is low, a low resistance connection between the lower layer Cu wiring and the carbon nanotube can be secured and at the same time, a preferable carbon nanotube can be formed.

### CROSS-REFERENCE TO RELATED APPLICATIONS

This application is based upon and claims the benefits of priority from the prior Japanese Patent Application No. 2004-289720, filed on Oct. 1, 2004, the entire contents of which are incorporated herein by reference.

### BACKGROUND OF THE INVENTION

1. Field of the Invention

The present invention relates to a wiring connection structure and a method for forming the same. More particularly, the present invention relates to a wiring connection structure which is used in a semiconductor apparatus for electrically connecting between wirings. The invention also pertains to a method for forming the same.

2. Description of the Related Art

In a semiconductor apparatus or a printed wiring board, a via structure is widely employed for electrically connecting between wirings which are present on different layers or planes. In the via structure, a via-hole is formed on an inter-layer insulating film or on a substrate and conductive materials are formed within the via-hole. In recent years, copper (Cu) is used exclusively for wiring materials to form a Cu wiring. Using the Cu wiring, a via is commonly formed as follows. A via-hole is formed in a predetermined position so as to communicate with the Cu wiring and then filled with conductive metal materials such as Cu.

For forming the via, use of carbon materials has been recently studied in addition to the use of metal materials such as Cu. The carbon materials contain a carbon cylindrical structure body (referred to as a “carbon element cylindrical structure body”) represented by a so-called carbon nanotube or cylindrical carbon fiber. In particular, the carbon nanotube has excellent chemical stability as well as various characteristics such as unique physical and electrical characteristics. Therefore, the carbon nanotube is taken notice of as formation materials for semiconductor apparatuses. Consequently, various studies have been still continued, for example, on the control of thickness or length of the carbon nanotube as well as the control of formation position or chirality.

By way of example, a wiring connection structure is described where the carbon nanotube is used for connection between wirings (see, e.g., Japanese Unexamined Patent Publication No. 2002-329723). FIG. 14 is a schematic sectional view of a conventional wiring connection structure using the carbon nanotube.

The conventional wiring connection structure as shown in FIG. 14 is as follows. On an inter-layer insulating film 101 formed on a lower layer side Cu wiring (referred to as a “lower layer Cu wiring”) 100, a via-hole 102 penetrating through the film 101 is formed. Aggregates of carbon nanotubes 103 extending in a direction perpendicular to the lower layer Cu wiring 100 are formed within the via-hole 102. The carbon nanotube 103 can be formed, for example, by using a Chemical Vapor Deposition (CVD) method. In the CVD method, carbon is perpendicularly oriented and grown using a catalyst metal 104 such as cobalt (Co), which is deposited on the lower layer Cu wiring 100 within the via-hole 102. On the upper end side of the thus formed carbon nanotube 103, a conductive layer such as a Cu wiring (referred to as an “upper layer Cu wiring”) (not shown) is formed. Thus, the lower layer Cu wiring 100 and the upper layer Cu wiring as the conductive layer are electrically connected by the carbon nanotube 103.

Further, another conventional wiring connection structure is proposed. The structure is formed as follows. On a dielectric material formed on a substrate having an active region, a via-hole communicating with the active region is formed. On the active region, a carbon nanotube is perpendicularly oriented and grown through a thin layer composed of tungsten (W). Further, a conductive layer is formed on the upper side of the carbon nanotube. Thus, the active region and the conductive layer are electrically connected by the carbon nanotube (see, e.g., Japanese Unexamined Patent Application Publication No. 2004-6864).

As described above, when carbon is perpendicularly oriented and grown by the CVD method to form a carbon element cylindrical structure body such as a carbon nanotube or a carbon fiber, an object to be treated is heated to a temperature necessary for the growth of the carbon nanotube, for example, about 400 to 900° C. during the CVD. Therefore, when the catalyst metal such as Co is deposited on the Cu wiring before the CVD, mutual thermal diffusion between Cu and the catalyst metal is caused due to the heat. Accordingly, there arises a problem that activity of the catalyst metal is reduced to result in inhibition of the growth of the carbon nanotube. As a result, for example, the carbon nanotube cannot be formed to an objective length or thickness, or cannot be formed to an objective density within the via-hole. Therefore, performance requirement of the semiconductor apparatus cannot be sufficiently satisfied in some cases.

### SUMMARY OF THE INVENTION

In view of the foregoing, it is an object of the present invention to provide a wiring connection structure comprising a wiring on which a preferable carbon element cylindrical structure body is formed.

It is another object of the present invention to provide a method for forming a wiring connection structure, wherein at the formation of a carbon element cylindrical structure body, activity of a catalyst metal is kept high so that a preferable carbon element cylindrical structure body can be formed on a wiring.

To accomplish the above object, there is provided a wiring connection structure, comprising a wiring, and a carbon element cylindrical structure body electrically connected to the wiring. The wiring connection structure is characterized in that the carbon element cylindrical structure body is formed on the wiring through a connection layer having conductivity.

To accomplish another object, there is provided a method for forming a wiring connection structure comprising a wiring and a carbon element cylindrical structure body electrically connected to the wiring. The method for forming a wiring connection structure is characterized by comprising the steps of (a) forming on the wiring a connection layer having conductivity, and (b) forming the carbon element cylindrical structure body on the connection layer.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 is a schematic sectional view showing an example of a wiring connection structure using a carbon nanotube.

FIG. 2 shows temperature dependency of sheet resistance in a sample formed by laminating Cu and various metals.

FIG. 3 is a schematic sectional view of a sample used in a sheet resistance measurement.

FIG. 4 shows temperature dependency of contact resistance between carbon nanotubes and various metals.

FIG. 5 is a schematic sectional view of a sample used in a contact resistance measurement.

FIG. 6 is a schematic sectional view of a step of forming a connection layer and a via-hole according to a first embodiment of the present invention.

FIG. 7 is a schematic sectional view of a step of forming a catalyst metal according to the first embodiment of the present invention.

FIG. 8 is a schematic sectional view of a step of forming a carbon nanotube according to the first embodiment of the present invention.

FIG. 9 is a schematic sectional view of a step of forming a via-hole according to a second embodiment of the present invention.

FIG. 10 is a schematic sectional view of a step of forming a connection layer and a catalyst metal according to the second embodiment of the present invention.

FIG. 11 is a schematic sectional view of a step of forming a carbon nanotube according to the second embodiment of the present invention.

FIG. 12 is a schematic sectional view of a step of forming a connection layer and a catalyst metal according to a third embodiment of the present invention.

FIG. 13 is a schematic sectional view of a step of forming a carbon nanotube according to the third embodiment of the present invention.

FIG. 14 is a schematic sectional view of a conventional wiring connection structure using a carbon nanotube.

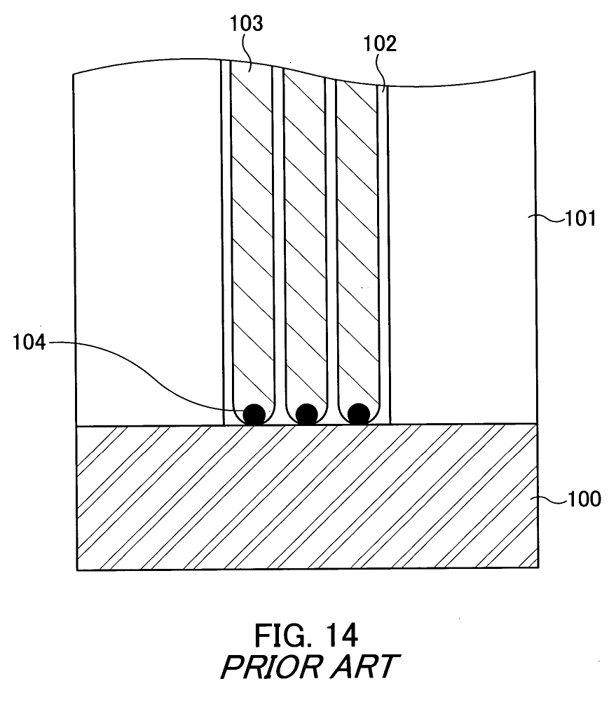

### DESCRIPTION OF THE PREFERRED EMBODIMENTS

Assuming that a carbon element cylindrical structure body is a carbon nanotube, preferred embodiments of the present invention will be described in detail below with reference to the accompanying drawings, wherein like reference numerals refer to like elements throughout.

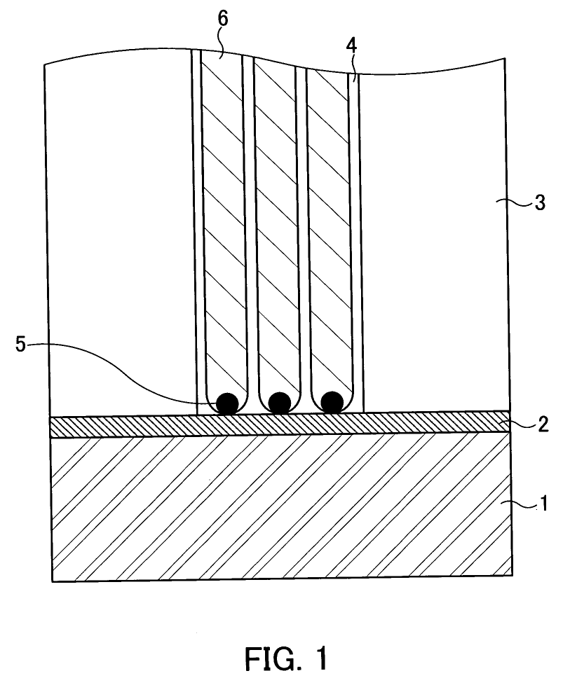

FIG. 1 is a schematic sectional view showing an example of a wiring connection structure using a carbon nanotube.

The wiring connection structure shown in FIG. 1 is as follows. A connection layer 2 having conductivity is formed on a lower layer Cu wiring 1. On the connection layer 2, an inter-layer insulating film 3, such as SiO₂ is formed. On the inter-layer insulating film 3, a via-hole 4 penetrating therethrough is formed. A plurality of carbon nanotubes 6 which contain a catalyst metal 5 such as Co and which extend in the direction perpendicular to the lower layer Cu wiring 1 are formed within the via-hole 4. On the upper end side of the carbon nanotubes 6, a conductive layer such as an upper layer Cu wiring (not shown) is formed. Thus, the lower layer Cu wiring 1 and the conductive layer as the upper layer are electrically connected through the carbon nanotubes 6. In addition, an insulating underlying layer such as SiO₂ (not shown herein) is normally provided on a lower layer of the lower layer Cu wiring I. The underlying: layer is provided also on a semiconductor substrate or another wiring layer.

The wiring connection structure as described above is formed, for example, by the following procedures. On the lower layer Cu wiring 1 formed on the underlying layer, the connection layer 2 is first formed to a predetermined thickness and thereon, the inter-layer insulating film 3 is formed. After that, a predetermined region of the inter-layer insulating film 3 is etched to form the via-hole 4 which reaches: the connection layer 2. Then, the catalyst metal 5 is deposited on the connection layer 2 which is exposed within the via-hole 4. Thereafter, by means of the CVD method, the carbon nanotubes 6 are grown within the via-hole 4 using the catalyst metal 5.

When the conductive connection layer 2 is provided between the lower layer Cu wiring 1 and the carbon nanotubes 6 as described above, the following advantages can be obtained. Even when a certain amount of heat necessary for growth of the carbon nanotubes is applied during the CVD, thermal diffusion of Cu in the lower layer Cu wiring 1 is suppressed so that activity of the catalyst metal 5 can be kept. As a result, an electrical connection between the lower layer Cu wiring 1 and the carbon nanotubes 6 is secured and at the same time, preferable carbon nanotubes 6 can be grown within the via-hole 4.

Accordingly, the connection layer 2 is desired to sufficiently have at least the following two properties. The thermal diffusion of Cu caused by a growth temperature of the carbon nanotubes 6 is suppressed, and contact resistance between the connection layer 2 and the carbon nanotubes 6 is low. Herein, these two properties are studied for selecting materials for the connection layer 2. The results thereof are described.

At first, thermal diffusion suppression of Cu is studied and the results thereof are described.

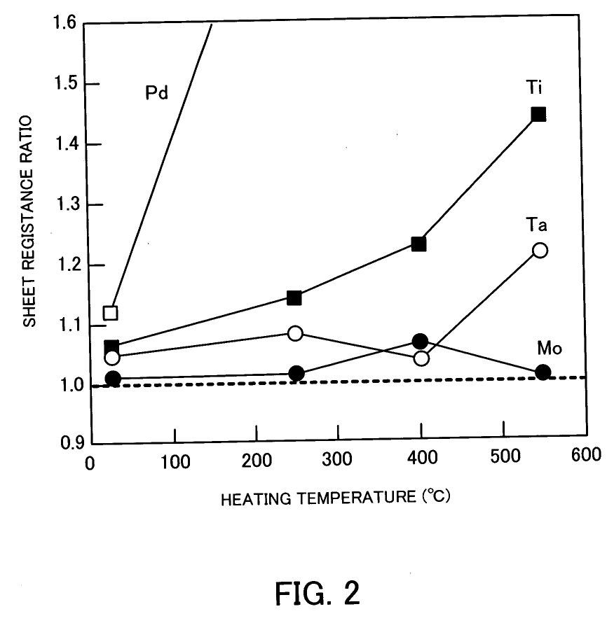

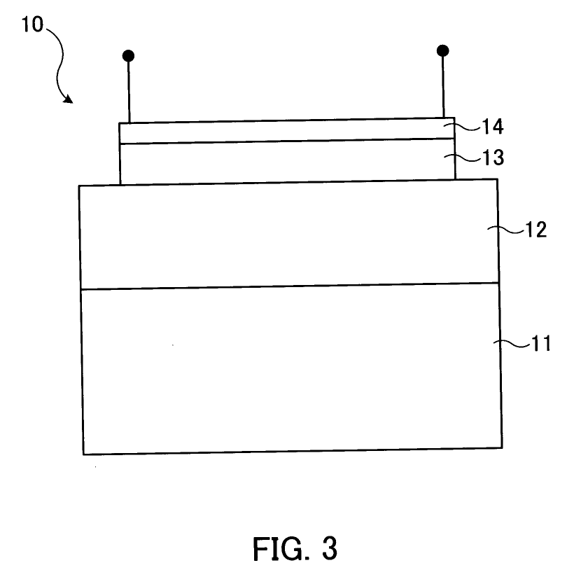

FIG. 2 shows temperature dependency of sheet resistance in a sample formed by laminating Cu and various metals. In FIG. 2, the horizontal axis shows the heating temperature (° C.) of the sample, and the vertical axis shows the sheet resistance ratio thereof. FIG. 3 is a schematic sectional view of a sample 10 used in a sheet resistance measurement.

Herein, as shown in FIG. 3, the following sample 10 is used for the sheet resistance measurement. On a Si substrate 11, a SiO₂ film 12 serving as an underlying layer is formed and thereon, a Cu layer 13 having a thickness of about 300 nm and a layer 14 composed of various metals, which has a thickness of about 5 nm, are laminated. The Cu layer 13 and the metal layer 14 correspond to the lower layer Cu wiring 1 and the connection layer 2, respectively. Any one of a molybdenum (Mo) layer, a tantalum (Ta) layer, a titanium (Ti) layer and a palladium (Pd) layer is used as the metal layer 14. This sample 10 is heated at an appropriate temperatures up to about 600° C. After being heated at each temperature, the sample 10 is cooled to a room temperature. The sheet resistance of a laminated product comprised of the Cu layer 13 and the metal layer-14 is measured. The heating time at each temperature is set to about 10 minutes.

In the sample 10, when the thermal diffusion of Cu is suppressed, rise of the sheet resistance is suppressed. The measurement results are as follows. As shown in FIG. 2, when the metal layer 14 is the Pd layer, the sheet resistance greatly rises with the rise of the heating temperature. On the other hand, when the metal layer 14 is any one of the Mo layer, the Ta layer and the Ti layer, the sheet resistance is kept relatively low even when the heating temperature rises. In particular, when the metal layer 14 is the Mo layer, the sheet resistance exhibits a low level within the whole measurement temperature range.

From the measurement results, the following facts are found. In view of the thermal diffusion suppression of Cu, when any one of Mo, Ta, Ti and Pd is independently used for the connection layer 2, Mo, Ta or Ti is preferred rather than Pd, and Mo or Ta is more preferred rather than Pd.

Subsequently, the contact resistance between various metals and the carbon nanotubes is studied and the results thereof are described.

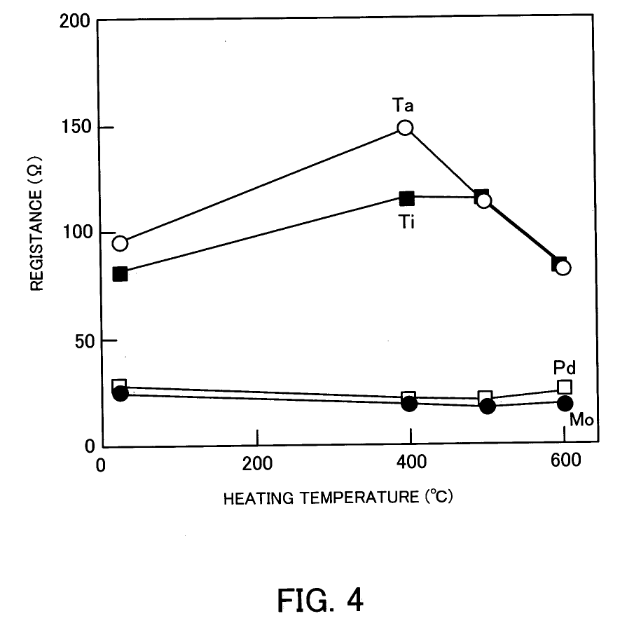

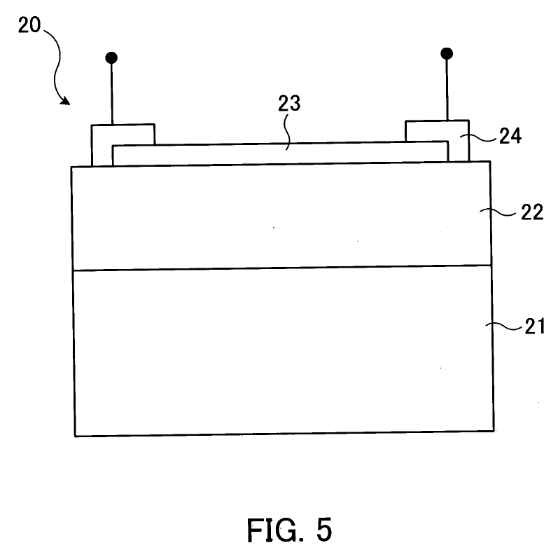

FIG. 4 shows the temperature dependency of the contact resistance between the carbon nanotubes and the various metals. In FIG. 4, the horizontal axis shows the heating temperature (° C.) of the sample, and the vertical axis shows the resistance (Ω) between two terminals. FIG. 5 is a schematic sectional view of a sample 20 used in a contact resistance measurement.

Herein, as shown in FIG. 5, the following sample 20 is used for the contact resistance measurement. On a Si substrate 21, a SiO₂ film 22 serving as an underlying layer is formed and thereon, a carbon nanotube 23 extending in a plane direction of the SiO₂ film 22 is formed. On both ends of the carbon nanotube 23, metal layers 24 are then formed. The carbon nanotube 23 and the metal layers 24 correspond to the carbon nanotubes 6 extending in the perpendicular direction and the connection layer 2, respectively. Any one of the Mo layer, the Ta layer, the Ti layer and the Pd layer is used as the metal layers 24. This sample 20 is heated at an appropriate temperature up to about 600° C. After being heated at each temperature, the sample 20 is cooled to a room temperature. The contact resistance between both ends of the carbon nanotube 23 and the metal layers 24 is measured. The heating time at each temperature is set to about 10 minutes.

The measurement results are as follows. As shown in FIG. 4, when the metal layers 24 are the Ta layer, a high contact resistance value is obtained. On the other hand, when the other metals are used for the metal layers 24, low resistance values are obtained in the order corresponding to the Ti layer, the Pd layer and the Mo layer. In particular, when the metal layers 24 are any one of the Pd layer and the Mo layer, the contact resistance exhibits a low level within the whole measurement temperature range.

From the measurement results, the following facts are found. In view of the low contact resistance, when any one of Mo, Ta, Ti and Pd is independently used for the connection layer 2, Mo, Ti or Pd is preferred rather than Ta, and Mo or Pd is more preferred rather than Ta.

Study results of two properties such as the thermal diffusion suppression of Cu and the low contact resistance, which are desired for the connection layer 2, are described above. As is apparent from the study results, a metal that satisfies both of the properties is Mo. Therefore, when the connection layer 2 in the wiring connection structure is configured by a single kind of metal, the Mo layer is used as the connection layer 2. At a result, even when heat is applied during the CVD for growing the carbon nanotubes 6, the thermal diffusion of Cu in the lower layer Cu wiring 1 is suppressed so that the activity of the catalyst metal 5 can be kept high. Accordingly, the low resistance connection between the lower layer Cu wiring 1 and the carbon nanotubes 6 can be secured and at the same time, the carbon nanotubes 6 can be preferably grown within the via-hole 4.

In addition, the connection layer 2 can be configured not only by a single kind of metal but also by plural kinds of metals. For example, Mo capable of satisfying the objective properties even when it is used independently may be alloyed with other metals for application to the connection layer 2. Examples of the metals alloyed with Mo include Ti and Co. As shown in FIGS. 2 and 4 above, even when being used independently, Ti realizes a certain level of the thermal diffusion suppression of Cu and the low contact resistance. Even when a MoTi alloy is used, both of the properties can be satisfied. In addition, when a MoCo alloy is used for the connection layer 2, Co which is contained in the alloy is allowed to act as a catalyst during the growth of the carbon nanotubes 6.

Further, the connection layer 2 may be formed to have a structure where two kinds of metals are laminated. In this case, the connection layer 2 is formed to have the following double-layered structure. On the lower layer Cu wiring 1 side, a metal layer that mainly suppresses the thermal diffusion of Cu is provided as a first layer. On the carbon nanotubes 6 side, a metal layer that mainly exhibits the low contact resistance is provided as a second layer. Both of the properties such as the thermal diffusion suppression of Cu and the low contact resistance can be satisfied also by using this laminated structure.

Examples of the laminated structure include a Ta/Ti laminated structure comprised of a Ta layer provided on the lower layer Cu wiring 1 side and a Ti layer provided on the carbon nanotubes 6 side, a Ta/Pd laminated structure comprised of a Ta layer provided on the lower layer Cu wiring 1 side and a Pd layer provided on the carbon nanotubes 6 side, and a Ta/Mo laminated structure comprised of a Ta layer provided on the lower layer Cu wiring 1 side and a Mo layer provided on the carbon nanotubes 6 side. A combination of laminated metals can be appropriately selected using the results of FIGS. 2 and 4. In addition, for each metal layer that configures the laminated structure, an alloy of the metals may be used.

Further, the connection layer 2 can be formed to have a laminated structure of three or more layers, if desired. For example, for the purpose of securing the connection strength between the metal layer provided on the lower layer Cu wiring 1 side and the metal layer provided on the carbon nanotubes 6 side, the connection layer 2 may be configured such that another metal layer for compensating the connection strength is inserted between both the metal layers. Also in this case, for each metal layer, an alloy of the metals can be used.

The configuration examples of the wiring connection structure are described above. In the wiring connection structure, the connection layer 2 can be formed by a method where metals used for the layer 2 are deposited using a sputtering method or a vapor deposition method. The connection layer 2 is formed to a thickness of about from 1 to 20 nm, preferably about from 2 to 10 nm. When the thickness of the connection layer 2 is less than 1 nm, it becomes difficult to sufficiently obtain an effect of the thermal diffusion suppression of Cu. On the contrary, when it is more than 20 nm, a value of conduction resistance between the lower layer Cu wiring 1 and the carbon nanotubes 6 is increased.

The catalyst metal 5 in the wiring connection structure can be formed by a method where metals used for the metal 5 are deposited using the sputtering method or the vapor deposition method. For growing the carbon nanotubes 6 using the CVD method, finally, the catalyst metal 5 may take any form of layers or particles.

In the wiring connection structure, the carbon nanotubes 6 may have any structure of a single layer structure or a multilayer structure. Further, the carbon nanotubes 6 may have both of the single layer structure and the multilayer structure within one via-hole 4. Each of the carbon nanotubes 6 may be present independently, or a plurality of carbon nanotubes 6 may take the form of a bundle. In addition, the carbon nanotubes 6 may have a peapod structure.

When growing the carbon nanotubes 6 using the CVD method, the growth can be performed by any method of a plasma CVD method or a thermal CVD method. When using the plasma CVD method, the growth of the carbon nanotubes 6 proceeds by a so-called tip growth where the catalyst metal 5 remains at a tip (an end of the upper layer Cu wiring side) within the carbon nanotubes 6. When using the thermal CVD method, the growth of the carbon nanotubes 6 proceeds by a so-called base growth where the catalyst metal 5 remains at a base (an end of the lower layer Cu wiring 1 side) within the carbon nanotubes 6.

The wiring connection structure using the carbon nanotube and the method for forming the same are described below by referring to specific examples.

At first, a first embodiment is described.

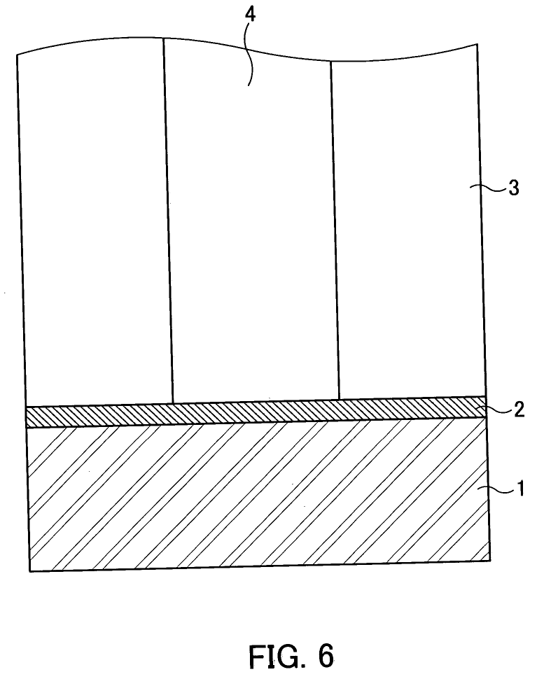

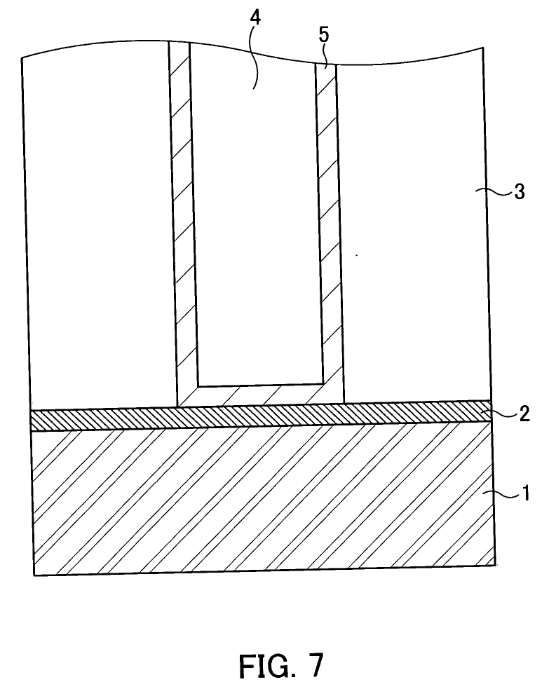

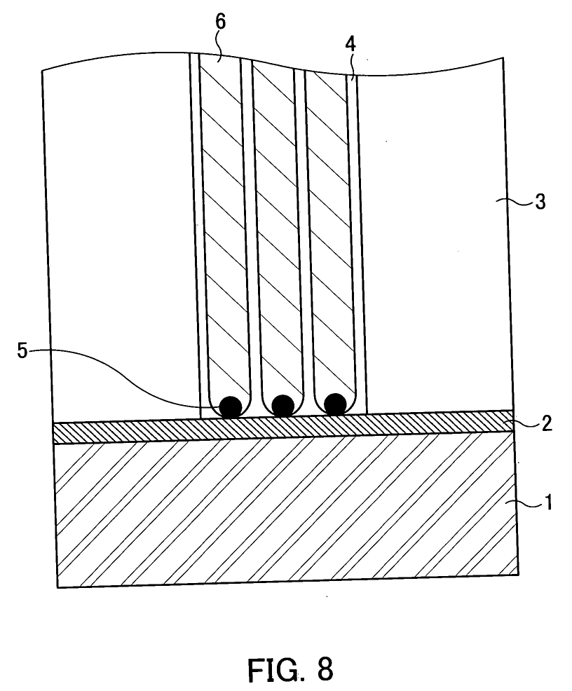

FIGS. 6 to 8 each illustrate a method for forming the wiring connection structure. FIG. 6 is a schematic sectional view of a step of forming the connection layer and via-hole according to the first embodiment of the present invention. FIG. 7 is a schematic sectional view of a step of forming the catalyst metal according to the first embodiment of the present invention. FIG. 8 is a schematic sectional view of a step of forming the carbon nanotube according to the first embodiment of the present invention.

The wiring connection structure of the first embodiment is formed as follows. As shown in FIG. 6, on the lower layer Cu wiring 1 having a thickness of about 100 nm, which is formed on an appropriate insulating underlying layer (not shown), Mo is first deposited to a thickness of about 5 nm using the sputtering method or the vapor deposition method to form the connection layer 2. Subsequently, SiO₂ having a thickness of about 350 nm is deposited as the inter-layer insulating film 3. Thereafter, on the inter-layer insulating film 3, the via-hole 4 is formed as follows. Using a patterning method, an opening of a resist film is formed in a region where a via is to be formed. Until the connection layer 2 is exposed, the inter-layer insulating film 3 is etched by dry etching using fluorine.

When forming the via-hole 4, the dry etching and the wet etching using, for example, hydrofluoric acid may be used at the same time. By doing so, the etching can be performed while suppressing damage given to the connection layer 2.

Subsequently, as shown in FIG. 7, a Co layer is deposited as the catalyst metal 5 within the via-hole 4. On this occasion, at first, Co is deposited to a thickness of about 2.5 nm on the whole surface by the sputtering method or by the vapor deposition method. Then, the Co layer is formed within the via-hole 4 by the lift-off technique using the resist film.

For the catalyst metal 5, Co is used herein. In place of Co, iron (Fe) or nickel (Ni) may be used. Further, an alloy containing these elements may be used. Herein, the catalyst metal 5 is in the form of a thin layer. It may be in the form of fine particles.

After thus forming the catalyst metal 5 on the connection layer 2, the carbon nanotubes 6 are grown within the via-hole 4 using the catalyst metal 5, as shown in FIG. 8.

The carbon nanotubes 6 can be grown using, for example, a thermal filament CVD method where gas dissociation is performed by a thermal filament. In this case, for example, the conditions for growing the carbon nanotubes 6 are set as follows. For a reaction gas, a mixed gas (C₂H₂/H₂=80 sccm/20 sccm) of acetylene (C₂H₂) and hydrogen (H₂) is introduced into a vacuum chamber. A pressure within the chamber is set to about 1000 Pa, a temperature of the object to be treated is set to about 600° C. and a temperature of the thermal filament is set to about 1800° C. The term “sccm” indicates a flow rate (mL/min) at 0° C. and at 101.3 kPa.

Further, the carbon nanotubes 6 can be grown also using a DC plasma thermal filament CVD method where the thermal filament CVD method is combined with a direct current (DC) plasma CVD method. In this case, for example, the conditions for growing the carbon nanotubes 6 are set as follows. For a reaction gas, a mixed gas (C₂H₂/H₂=80 sccm/20 sccm) of acetylene (C₂H₂) and hydrogen (H₂) is introduced into a vacuum chamber. A pressure within the chamber is set to about 1000 Pa, a temperature of the object to be treated is set to about 600° C. and a temperature of the thermal filament is set to about 1800° C.

Further, the carbon nanotubes 6 can be grown also using a normal thermal CVD method which is conventionally performed generally. In this case, for example, the conditions for growing the carbon nanotubes 6 are set as follows. For a reaction gas, a mixed gas (C₂H₂/H₂=80 sccm/20 sccm) of acetylene (C₂H₂) and hydrogen (H₂) is introduced into a vacuum chamber. A pressure within the chamber is set to about 200 Pa and a temperature of the object to be treated is set to about 900° C. However, the temperature of the object to be treated becomes higher, as compared with the case using the thermal filament CVD method. Therefore, selection of materials for the connection layer 2 must be taken notice of.

For allowing the carbon nanotubes 6 to self-orient and grow in the perpendicular direction onto the connection layer 2, a DC electric field of, for example, about −400 volts is applied to the object to be treated, with respect to the grounded chamber during the CVD. When the DC electric field is thus applied, the carbon nanotubes 6 can be oriented and grown in the perpendicular direction.

As described above, in the first embodiment, the connection layer 2 is formed using Mo and thereon, the catalyst metal 5 and the carbon nanotubes 6 are formed. As a result, the thermal diffusion of Cu in the lower layer Cu wiring 1 is suppressed during the CVD. Therefore, the preferable carbon nanotubes 6 can be formed and at the same time, the carbon nanotubes 6 and the lower layer Cu wiring 1 can be electrically connected through low resistance.

Next, a second embodiment of the present invention is described.

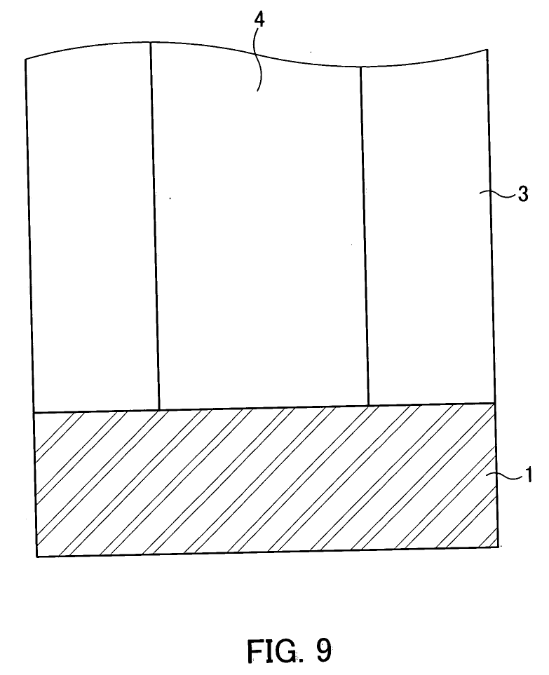

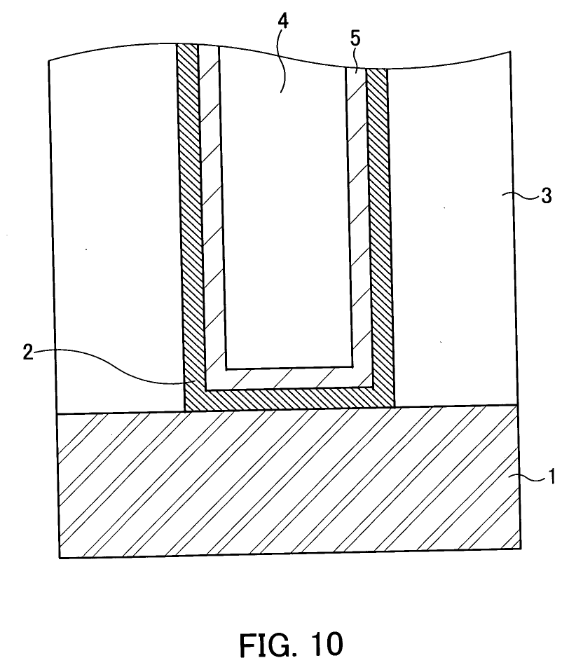

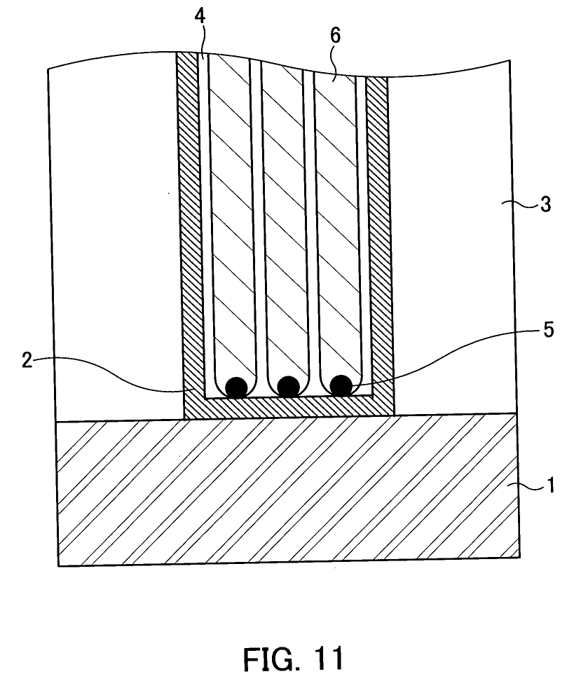

FIGS. 9 to 11 illustrate a method for forming the wiring connection structure according to the second embodiment of the present invention. FIG. 9 is a schematic sectional view of a step of forming the via-hole according to the second embodiment of the present invention. FIG. 10 is a schematic sectional view of a step of forming the connection layer and catalyst metal according to the second embodiment of the present invention. FIG. 11 is a schematic sectional view of a step of forming the carbon nanotube according to the second embodiment of the present invention.

The wiring connection structure of the second embodiment is formed as follows. As shown in FIG. 9, on the lower layer Cu wiring 1 having a thickness of about 100 nm, which is formed on an appropriate underlying layer (not shown), SiO₂ is first deposited to a thickness of about 350 nm to form the inter-layer insulating film 3. Thereafter, on the inter-layer insulating film 3, the via-hole 4 is formed as follows. Using a patterning method, an opening of a resist film is formed in a region where a via is to be formed. Until the lower layer Cu wiring 1 is exposed, the inter-layer insulating film 3 is etched by the dry etching using fluorine. When forming the via-hole 4, the dry etching and the wet etching using, for example, hydrofluoric acid may be used at the same time.

Subsequently, on the whole surface, Mo is deposited to a thickness of about 5 nm and then, Co is deposited to a thickness of about 2.5 nm by the sputtering method or by the vapor deposition method. Then, the Mo layer as the connection layer 2 and the Co layer as the catalyst metal 5 are formed within the via-hole 4 by the lift-off technique using the resist film, as shown in FIG. 10. For the catalyst metal 5, Fe or Ni, or an alloy containing these elements may be used in addition to Co. The catalyst metal 5 may be any form of a thin layer or of fine particles.

After thus forming the connection layer 2 and the catalyst metal 5 within the via-hole 4, the carbon nanotubes 6 are grown within the via-hole 4 using the catalyst metal 5, as shown in FIG. 11. In the same manner as in the first embodiment, the carbon nanotubes 6 can be grown using the normal thermal CVD method in addition to the thermal filament CVD method or the DC plasma thermal filament CVD method. The conditions for growing the carbon nanotubes 6 using each CVD method can be set to the same conditions as, for example, those in the first embodiment.

As described above, in the second embodiment, the connection layer 2 and the catalyst metal 5 are formed within the via-hole 4 communicating with the lower layer Cu wiring 1. Then, the carbon nanotubes 6 are formed. Also by using this method and configuration, the thermal diffusion of Cu in the lower layer Cu wiring 1 is suppressed during the CVD. As a result, the preferable carbon nanotubes 6 can be formed and at the same time, the carbon nanotubes 6 and the lower layer Cu wiring 1 can be electrically connected through the low resistance.

Next, a third embodiment is described.

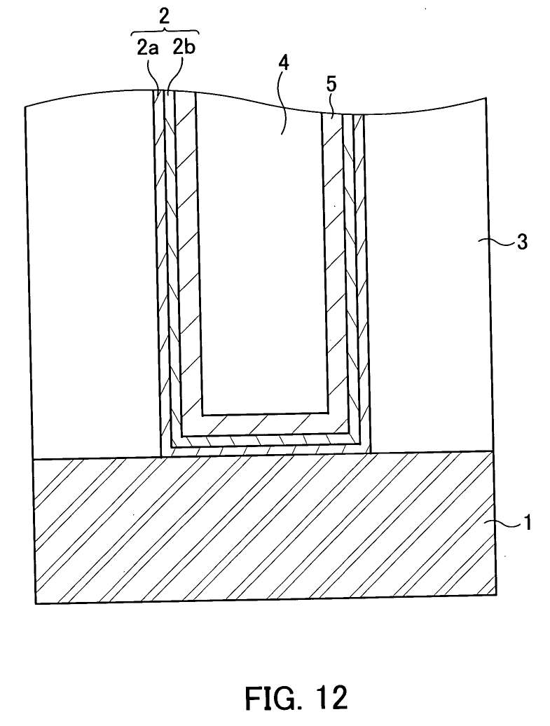

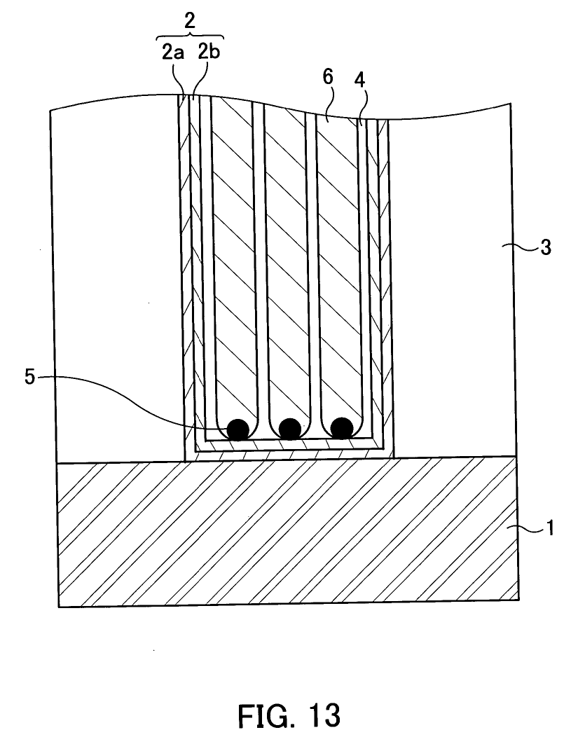

FIGS. 12 and 13 illustrate a method for forming the wiring connection structure according to the third embodiment of the present invention. FIG. 12 is a schematic sectional view of a step of forming the connection layer and catalyst metal according to the third embodiment of the present invention. FIG. 13 is a schematic sectional view of a step of forming the carbon nanotube according to the third embodiment of the present invention.

In the same manner as in the second embodiment, the wiring connection structure of the third embodiment is formed as follows. As shown in FIG. 12, on the lower layer Cu wiring 1 having a thickness of about 100 nm, which is formed on an underlying layer (not shown), SiO₂ is first deposited to a thickness of about 350 nm to form the inter-layer insulating film 3. Then, the via-hole 4 communicating with the lower layer Cu wiring 1 is formed using the patterning technique.

Subsequently, on the whole surface, Ta is deposited to a thickness of about 5 nm and then, Ti is deposited to a thickness of about 2.5 nm by the sputtering method or by the vapor deposition method. Further thereon, Co is deposited to a thickness of about 2.5 nm. Thereafter, a laminated structure as the connection layer 2 comprised of the Ta layer 2a and the Ti layer 2b is formed within the via-hole 4 and then, the Co layer as the catalyst metal 5 is formed on the Ti layer 2b by the lift-off technique using the resist film, as shown in FIG. 12. For the catalyst metal 5, Fe or Ni, or an alloy containing these elements may be used in addition to Co. The catalyst metal 5 may be any form of a thin layer or of fine particles.

After thus forming the connection layer 2 and the catalyst metal 5 within the via-hole 4, the carbon nanotubes 6 are grown within the via-hole 4 using the catalyst metal 5, as shown in FIG. 13. In the same manner as in the first embodiment, the carbon nanotubes 6 can be grown using the normal thermal CVD method in addition to the thermal filament CVD method or the DC plasma thermal filament CVD method. The conditions for growing the carbon nanotubes 6 using each CVD method can be set to the same conditions as, for example, those in the first embodiment.

As described above, in the third embodiment, the connection layer 2 having the Ta/Ti laminated structure and the catalyst metal 5 are formed within the via-hole 4 communicating with the lower layer Cu wiring 1. Then, the carbon nanotubes 6 are formed. This connection layer 2 having the double-layered structure has the following properties. The Ta layer 2a formed on the lower layer Cu wiring 1 side mainly suppresses the thermal diffusion of Cu during the CVD. The Ti layer 2b formed on the carbon nanotubes 6 side mainly realizes the low contact resistance between the connection layer 2 and the carbon nanotubes 6. As a result, the preferable carbon nanotubes 6 can be formed and at the same time, the carbon nanotubes 6 and the lower layer Cu wiring 1 can be electrically connected through the low resistance.

Also when the connection layer 2 is formed to have the Ta/Pd laminated structure or Ta/Mo laminated structure previously exemplified, the wiring connection structure can be formed in the same manner as in the third embodiment. Further, the same effect can be obtained.

As described above, in the wiring connection structure using the carbon nanotubes 6, the carbon nanotubes 6 are formed on the lower layer Cu wiring 1 through the connection layer 2 having conductivity. Therefore, an electrical connection between the lower layer Cu wiring 1 and the carbon nanotubes 6 is secured. At the same time, the thermal diffusion of Cu in the lower layer Cu wiring 1 is suppressed so that the preferable carbon nanotubes 6 can be formed. Thus, the wiring connection structure using the carbon nanotubes 6, which has high connection reliability, is realized.

The present invention is described above, assuming that the carbon element cylindrical structures body is a carbon nanotube. In addition, even when the carbon element cylindrical structure body is other carbon element cylindrical structure body, for example, a carbon fiber which is formed almost into a cylinder shape, the same effect as that described above can be obtained. Further, even when such cylindrical carbon fibers are present together with carbon nanotubes, the same effect as that described above can be obtained. Even when such a carbon element cylindrical structure body contains other structure body containing a carbon element, the same effect as that described above can be obtained.

In the present invention, the conductive connection layer is provided between the wiring and the carbon element cylindrical structure body. Therefore, even when heat is applied during the formation of the carbon element cylindrical structure body, the thermal diffusion in wiring materials is suppressed. Accordingly, such a harmful effect that may be caused by the thermal diffusion can be avoided. More specifically, such a harmful effect that the activity of the catalyst metal is reduced to prevent formation of the preferable carbon element cylindrical structure body can be avoided. As a result, the connection reliability between wirings which are connected through the carbon element cylindrical structure body can be enhanced and a higher quality of products can be realized.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A wiring connection structure, comprising:
a wiring, and
a carbon element cylindrical structure body electrically connected to the wiring,
wherein the carbon element cylindrical structure body is formed on the wiring through a connection layer having conductivity.

2. The wiring connection structure according to claim 1, wherein the connection layer suppresses diffusion of materials for the wiring, and is connected to the carbon element cylindrical structure body through low contact resistance.

3. The wiring connection structure according to claim 1, wherein the connection layer is a molybdenum layer.

4. The wiring connection structure according to claim 1, wherein the connection layer is a layer containing molybdenum.

5. The wiring connection structure according to claim 1, wherein the connection layer has a laminated structure comprising a first layer which is provided on the wiring side and which suppresses diffusion of materials for the wiring, and a second layer which is provided on the carbon element cylindrical structure body side and which is connected to the carbon element cylindrical structure body through low contact resistance.

6. The wiring connection structure according to claim 1, wherein the connection layer has a tantalum/titanium laminated structure comprising a tantalum layer provided on the wiring side, and a titanium layer provided on the carbon element cylindrical structure body side.

7. The wiring connection structure according to claim 1, wherein the connection layer has a tantalum/palladium laminated structure comprising a tantalum layer provided on the wiring side, and a palladium layer provided on the carbon element cylindrical structure body side.

8. The wiring connection structure according to claim 1, wherein the connection layer has a tantalum/molybdenum laminated structure comprising a tantalum layer provided on the wiring side, and a molybdenum layer provided on the carbon element cylindrical structure body side.

9. The wiring connection structure according to claim 1, wherein the carbon element cylindrical structure body contains a catalyst metal for forming the carbon element cylindrical structure body.

10. The wiring connection structure according to claim 1, wherein the carbon element cylindrical structure body is a carbon nanotube.

11. The wiring connection structure according to claim 9, wherein the catalyst metal contains one or more elements selected from iron, nickel and cobalt.

12. A method for forming a wiring connection structure comprising a wiring and a carbon element cylindrical structure body electrically connected to the wiring, comprising the steps of:
forming on the wiring a connection layer having conductivity, and
forming the carbon element cylindrical structure body on the connection layer.

13. The method for forming a wiring connection structure according to claim 12, further comprising the steps of:
forming, after completion of the formation step of the connection layer, a via-hole that communicates with the connection layer, and
forming the carbon element cylindrical structure body on the connection layer exposed on the via-hole bottom face.

14. The method for forming a wiring connection structure according to claim 12, further comprising the steps of:
forming a via-hole that communicates with the wiring,
forming, after completion of the formation step of the via-hole, the connection layer on the wiring exposed on the via-hole bottom face, and
forming the carbon element cylindrical structure body on the connection layer.

15. The method for forming a wiring connection structure according to claim 12, further comprising the steps of:
depositing, after completion of the formation step of the connection layer, a catalyst metal on the connection layer, and
forming the carbon element cylindrical structure body on the connection layer using the catalyst metal.

16. The method for forming a wiring connection structure according to claim 12, wherein the carbon element cylindrical structure body is formed on the connection layer using a Chemical Vapor Deposition method.

17. The method for forming a wiring connection structure according to claim 16, wherein when forming the carbon element cylindrical structure body on the connection layer using a Chemical Vapor Deposition method, an electric field is applied in a uniform direction to grow carbon on the connection layer.
